(19) United States
(12) Patent Application Publication
(10) Pub. No.: US 2015/0244289 A1
(43) Pub. Date: Aug. 27, 2015

(54) VIBRATOR, MANUFACTURING METHOD THEREFOR, AND ELECTRONIC APPLIANCE

(71) Applicant: SEIKO EPSON CORPORATION, Tokyo (JP)

(72) Inventor: Takahiko YOSHIZAWA, Sakata-shi (JP)

(21) Appl. No.: 14/625,164

(22) Filed: Feb. 18, 2015

(30) Foreign Application Priority Data
Feb. 21, 2014 (JP) 2014-031621

(51) Int. Cl. H02N 1/00; B81C 1/00; B81B 3/00

(52) U.S. Cl. CPC H02N 1/006; B81B 3/001; B81C 1/00928

(57) ABSTRACT

A vibrator according to the invention includes: a substrate; a lower electrode that is formed on the substrate and has a through hole formed therein; an upper electrode that is disposed above the lower electrode so as to be spaced apart from the lower electrode, and includes a protruding portion that protrudes toward the through hole; and a facing portion that is formed on the substrate, and faces the protruding portion. A distance between the facing portion and the protruding portion is smaller than a distance between the lower electrode and the upper electrode.

### BACKGROUND

1. Technical Field

The present invention relates to a vibrator, a manufacturing method therefor, and an electronic appliance.

2. Related Art

Functional elements (vibrators) manufactured by using MEMS (micro electro mechanical systems) technology are known. A typical functional element manufactured by MEMS has a structure in which one of a pair of opposing electrodes spaced apart from each other is fixed to a substrate and the other electrode is supported by the substrate so as to form a single-anchored beam or double-anchored beam shape. The other electrode is a movable electrode capable of being vibrated and deformed.

Such a vibrator including a fixed electrode and a movable electrode is usually manufactured through an etching step in which the movable electrode is mobilized (released). Such release etching is generally wet etching, and thus a situation may occur in which the fixed electrode and the movable electrode adhere to each other due to the surface tension of a liquid while the movable electrode is released and dried, and the fixed electrode and the movable electrode are not easily separated from each other. This phenomenon is called sticking, and may reduce the manufacturing yield and the like of the vibrator. To address this phenomenon, for example, JP-A-2006-095632 discloses an MEMS element including a movable portion having a protrusion, and a method for manufacturing such a MEMS element.

A cause of the sticking can be that in the drying step performed after wet etching, when a liquid (etchant or cleaning solution) evaporates in a state in which a meniscus is formed between two objects (for example, electrodes), a force (surface tension) bringing the two objects closer to each other acts, as a result of which the two objects (for example, electrodes) adhere to each other. Accordingly, even if a meniscus is formed, if a precaution can be taken to prevent the two objects from adhering to (coming into contact with) each other, the occurrence of sticking can be suppressed. Also, the adhesion (the degree of sticking) of two objects increases as the contact area of the two objects increases.

As with the element disclosed in JP-A-2006-095632 described above, forming a protrusion on the surface of an electrode is considered to be effective in suppressing sticking to some extent. However, with the element disclosed in JP-A-2006-095632, it is difficult to dispose electrodes in facing relationship with a distance smaller than the height of the protrusion in an area other than the protrusion of the electrode. Accordingly, there is a limit on reducing the spacing distance between the electrodes, and forming such a protrusion requires some compromise in sensitivity and the like when used as a sensor. Also, the protrusion disclosed in the above document has a flat tip portion as illustrated in the diagrams, and thus the contact area when the protrusion comes into contact with the other electrode disposed in facing relationship is large, as a result of which sticking may occur at the tip portion of the protrusion. Furthermore, the protrusion is formed by utilizing a difference in the growth rate of the thermal oxide film caused due to different types of impurities doped in silicon, and the impurities are diffused by heat. Accordingly, the resulting tip portion has an edgeless (blunt) shape, and it is difficult to form an edged (sharp) tip portion. For the reasons given above, with the element disclosed in JP-A-2006-095632, the effect of suppressing sticking obtained by using the protrusion is not necessarily high.

### SUMMARY

An advantage of some aspects of the invention is to provide a vibrator that has a high sensitivity, does not easily cause sticking and can be manufactured in a high yield, a method for manufacturing such a vibrator, and an electronic appliance.

The invention is provided to solve at least a part of the problem described above, and can be implemented as the following aspects or application examples.

### Application Example 1

A vibrator according to one aspect of the invention includes: a substrate; a lower electrode that is formed on the substrate and has a through hole formed therein; an upper electrode that is disposed above the lower electrode so as to be spaced apart from the lower electrode, and includes a protruding portion that protrudes toward the through hole; and a facing portion that is formed on the substrate, and faces the protruding portion, and a distance between the facing portion and the protruding portion is smaller than a distance between the lower electrode and the upper electrode.

With this vibrator, the distance between the lower electrode and the upper electrode is smaller than the height of the protruding portion, and it is therefore possible to obtain a high sensitivity when the vibrator is used as a sensor. In addition, in this vibrator, when the lower electrode and the upper electrode are brought closer to each other, the protruding portion and the facing portion come into contact with each other before the lower electrode and the upper electrode come into contact with each other, and thus even if the lower electrode and the upper electrode are brought closer to each other, the spacing between the lower electrode and the upper electrode can be secured. Accordingly, the vibrator of the invention is unlikely to cause sticking when manufactured through wet etching, and thus can be manufactured in a high yield.

### Application Example 2

In application example 1, the protruding portion may come into contact with the facing portion when the upper electrode is displaced toward the substrate, and a contact area when the protruding portion and the facing portion are in contact with each other may be 1 μm² or less.

In this vibrator, the contact area between the protruding portion and the facing portion is small, and thus sticking between the protruding portion and the facing portion is very unlikely to occur.

### Application Example 3

In application example 1 or 2, the upper electrode may include a fixed portion disposed on the substrate, a movable portion disposed so as to face the lower electrode, and a support portion that supports the movable portion by coupling the movable portion to the fixed portion, and the protruding portion may be disposed on the movable portion.

### Application Example 4

A method for manufacturing a vibrator according to one aspect of the invention includes: forming a first semiconductor layer on a substrate; forming a facing portion and a first oxide film formed on a surface of the facing portion by thermally oxidizing the first semiconductor layer; forming an opening through which the first oxide film is exposed by forming a second semiconductor layer on the substrate and the first oxide film, and patterning the second semiconductor layer; forming a lower electrode and a second oxide film formed on a surface of the lower electrode by thermally oxidizing the second semiconductor layer; forming a third semiconductor layer on the substrate, the first oxide film and the second oxide film; forming an upper electrode by patterning the third semiconductor layer; and etching the first oxide film and the second oxide film, and the second semiconductor layer has a higher impurity concentration than the first semiconductor layer.

According to the manufacturing method of this application example, the first oxide film can be formed so as to have a smaller thickness than the thickness of the second oxide film. Accordingly, it is possible to easily manufacture a vibrator in which the distance between the facing portion and the protruding portion is smaller than the distance between the lower electrode and the upper electrode.

### Application Example 5

The method according to application example 4 may include implanting an impurity into the second semiconductor layer, which is performed between the step of forming the second semiconductor layer and the step of forming the upper electrode.

By doing so, even if the same material is selected to form the first semiconductor layer and the second semiconductor layer, the impurity concentration of the second semiconductor layer can be increased as compared to the impurity concentration of the first semiconductor layer, and the first oxide film can be formed so as to have a smaller thickness than the thickness of the second oxide film.

### Application Example 6

An electronic appliance according to one aspect of the invention includes the vibrator according to any one of application examples 1 to 3 and a circuit unit that drives the vibrator.

Because the electronic appliance includes the above-described vibrator, the distance between the lower electrode and the upper electrode is smaller than the height of the protruding portion, and it is therefore possible to obtain a high sensitivity when it is used as a sensor. In addition, in the electronic appliance containing the above vibrator, when the lower electrode and the upper electrode are brought closer to each other, the protruding portion and the facing portion come into contact with each other before the lower electrode and the upper electrode come into contact with each other. Accordingly, even when the lower electrode and the upper electrode are brought closer to each other, the spacing between the lower electrode and the upper electrode can be secured. For this reason, the electronic appliance of the invention is unlikely to cause sticking when manufactured through wet etching, and thus can be manufactured in a high yield.

In this specification, regarding the term “on”, for example, an expression such as “a specific element (hereinafter referred to as ‘element B’) is formed “on” another specific element (hereinafter referred to as ‘element A’)” encompasses the case where the element B is formed directly on the element A, and the case where the element B is formed on the element A with another element interposed therebetween as long as the advantageous effects of the invention are not impaired.

Likewise, the terms “upper” and “lower” as used in, for example, “upper electrode” and “lower electrode” are not intended to indicate the up down relationship in a state in which the vibrator is installed, but to indicate the up down relationship in a state in which the substrate is located on the lower side irrespective of the state in which the vibrator is installed. Accordingly, for example, even if the vibrator is installed in a state in which the upper electrode is located on the lower side, the upper electrode is to be construed as the electrode located on the upper side as viewed in a state in which the substrate is located on the lower side.

### BRIEF DESCRIPTION OF THE DRAWINGS

The invention will be described with reference to the accompanying drawings, wherein like numbers reference like elements.

FIG. 1 is a schematic diagram showing a cross section of a vibrator according to an embodiment of the invention.

FIG. 2 is a schematic diagram of the vibrator according to the embodiment of the invention shown in plan view.

FIG. 3 is a schematic diagram showing a cross section of a relevant part of the vibrator according to the embodiment of the invention.

FIG. 4 is a schematic diagram showing, in cross section, a step of a method for manufacturing a vibrator according to an embodiment of the invention.

FIG. 5 is a schematic diagram showing, in cross section, a step of the method for manufacturing a vibrator according to the embodiment of the invention.

FIG. 6 is a schematic diagram showing, in cross section, a step of the method for manufacturing a vibrator according to the embodiment of the invention.

FIG. 7 is a schematic diagram showing, in cross section, a step of the method for manufacturing a vibrator according to the embodiment of the invention.

FIG. 8 is a schematic diagram showing, in cross section, a step of the method for manufacturing a vibrator according to the embodiment of the invention.

FIG. 9 is a schematic diagram showing, in cross section, a step of the method for manufacturing a vibrator according to the embodiment of the invention.

FIG. 10 is a circuit diagram showing an oscillator according to an embodiment of the invention.

FIG. 11 is a circuit diagram showing an oscillator according to a variation of the embodiment of the invention.

### DESCRIPTION OF EXEMPLARY EMBODIMENTS

Hereinafter, embodiments of the invention will be described. It is to be understood that the embodiments given below are intended to describe examples of the invention, and thus the scope of the invention is not limited by the following embodiments. The invention also encompasses various types of variations carried out within the scope that does not change the gist and spirit of the invention. Note that all of the constituent elements described below are not necessarily essential to the invention.

1. Vibrator

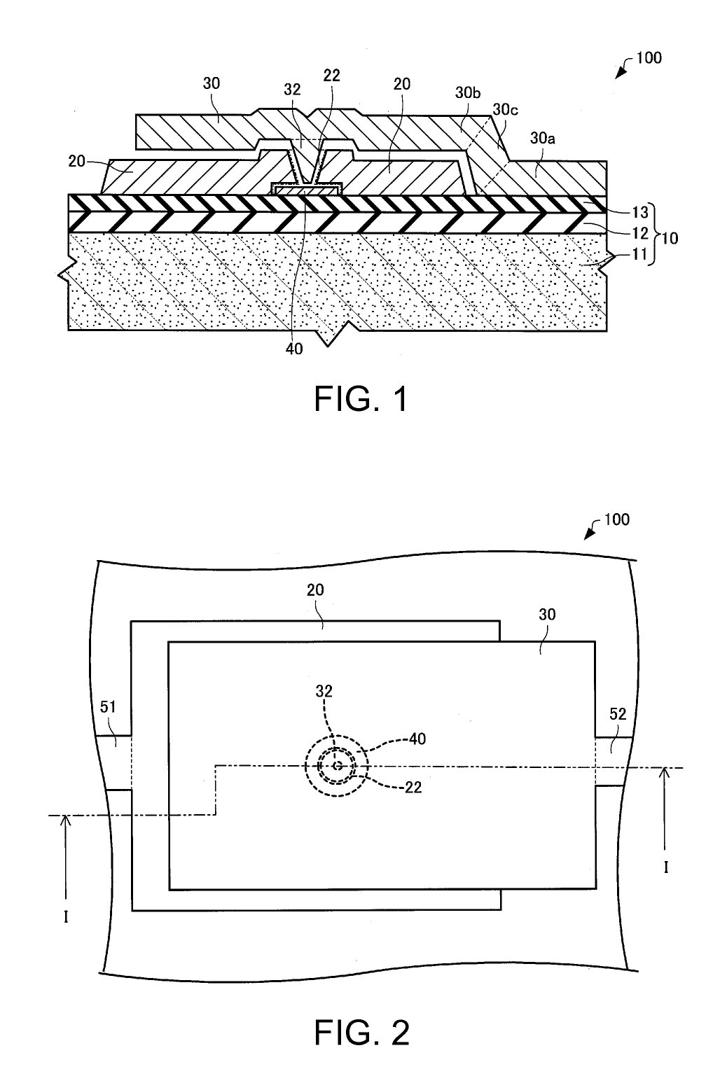

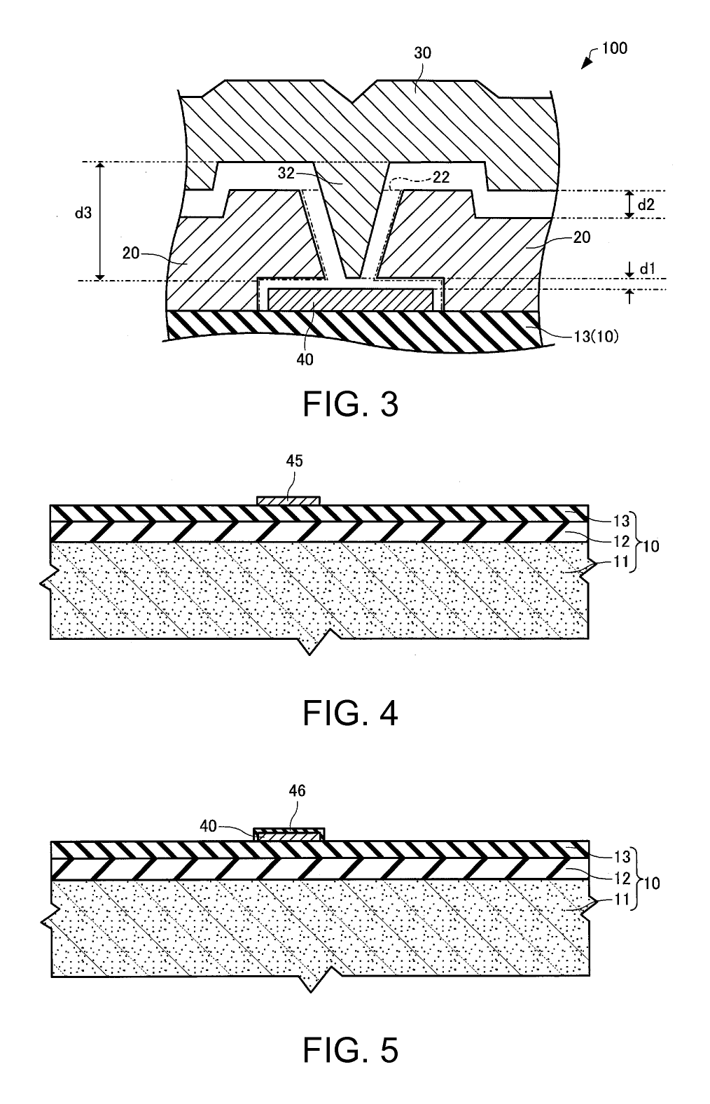

A vibrator 100 according to an embodiment of the invention includes a substrate 10, a lower electrode 20, an upper electrode 30, and a facing portion 40. FIG. 1 is a schematic diagram showing a cross section of the vibrator 100 according to the present embodiment. FIG. 2 is a schematic diagram of the vibrator 100 of the present embodiment shown in plan view. FIG. 3 is a schematic diagram showing a cross section of a relevant part of the vibrator 100 of the present embodiment. FIG. 1 shows a cross section taken along the line I-I of FIG. 2, and FIG. 3 shows an enlarged view of the vicinity of a protruding portion 32 and the facing portion 40 shown in FIG. 1.

1.1. Substrate

There is no particular limitation on the substrate 10 as long as the substrate can provide an insulating surface as the surface on which the electrodes of the vibrator are disposed. Also, the substrate 10 may be a single layer or may be a laminate of a plurality of layers. The substrate 10 can be, for example, a monocrystalline semiconductor substrate, a silicon (Si) substrate, a gallium arsenide (GaAs) substrate, or the like. It is also possible to use, as the substrate 10, various types of substrates such as a ceramic substrate, a glass substrate, a sapphire substrate, and a synthetic resin substrate. The substrate 10 is preferably a monocrystalline silicon substrate. The substrate 10 has a thickness of, for example, 10 μm to 1000 μm.

The substrate 10 may include insulating underlying layers as shown in FIG. 1. In the example shown in the diagram, the substrate 10 includes a silicon substrate (support substrate 11), a LOCOS (local oxidation of silicon) insulating layer (first underlying layer 12), which may be a trench insulating layer, a semi-recessed LOCOS insulating layer or the like, formed on a surface of the silicon substrate, and a second underlying layer 13 formed on the first underlying layer 12. The second underlying layer 13 may be made of, for example, silicon nitride (Si₃N₄). In a configuration in which the vibrator 100 is housed in a cavity, the second underlying layer 13 may be used as an etching stopper layer when forming the cavity.

1.2. Lower Electrode

The lower electrode 20 is formed on the substrate 10. There is no particular limitation on the shape of the lower electrode 20, and the shape can be designed as appropriate according to the function or sensitivity required for the vibrator. The lower electrode 20 has a through hole 22 formed therein. The lower electrode 20 is paired with the upper electrode 30 so as to constitute a sensor unit of the vibrator 100. The lower electrode 20 may include interconnects for inputting or outputting signals. In the example shown in FIGS. 1 and 2, the lower electrode 20 is formed in a rectangular shape in plan view, and is electrically connected to an interconnect 51 formed unitarily with the lower electrode 20.

There is no particular limitation on the thickness of the lower electrode 20, and the thickness can be, for example, 100 nm or more and 1 μm or less. The lower electrode 20 is made of a conductive material such as, for example, polycrystalline silicon (semiconductor) doped with an impurity. Examples of the impurity include arsenic (As), phosphorus (P), and boron (B). The impurity can be introduced by, for example, forming a film by sputtering an impurity-containing material, or by ion implantation. The impurity may be activated by heat treatment.

The lower electrode 20 is formed by forming a polycrystalline silicon layer on the entire surface of the substrate 10 by, for example, a CVD (chemical vapor deposition) method, a sputtering method or the like, followed by patterning using a photolithography technique and an etching technique. The etching technique used at this time may be wet etching, dry etching or the like. In the case where both the lower electrode 20 and the facing portion 40 are made of polycrystalline silicon, the polycrystalline silicon forming the lower electrode 20 has a higher impurity concentration than the impurity concentration of the polycrystalline silicon forming the facing portion 40. The impurity concentration of the lower electrode 20 can be adjusted by using a (doped) material having a high impurity concentration or by performing ion implantation when forming the lower electrode 20.

The through hole 22 is a hole passing through the lower electrode 20 in a thickness direction thereof. In a plan view of the lower electrode 20 as viewed from above, at least a part of the facing portion 40 can be seen through the through hole 22. That is, the through hole 22 of the lower electrode 20 allows at least a part of the facing portion 40 to be exposed upward.

In addition, the through hole 22 is formed so as to have a shape and a size that allow a protruding portion (described later) formed on the upper electrode 30 to pass through the through hole 22 and come into contact with the facing portion 40. The through hole 22 is formed at such a position that the protruding portion 32 can come into contact with the facing portion 40 within the through hole 22.

There is no particular limitation on the shape of the through hole 22, but the through hole 22 preferably has such a shape that the protruding portion 32 of the upper electrode 30 and the lower electrode 20 do not come into contact with each other if the upper electrode 30 is displaced toward the substrate 10. The through hole 22 may be configured to have a side surface having a shape that is similar to the outer shape of the side surface of the protruding portion 32 and is larger than the side surface of the protruding portion 32 such that the spacing distance between the protruding portion 32 and the lower electrode 20 within the through hole 22 is a predetermined distance. Furthermore, it is more preferable that the through hole 22 has such a shape that, in a cross section of the through hole 22 taken along a plane parallel to the substrate 10, the area of the cross section of the through hole 22 is reduced from the upper surface toward the lower surface of the lower electrode 20. By forming the through hole 22 so as to have such a shape, the protruding portion 32 of the upper electrode 30 can be sharpened (tapered) toward the substrate 10. The cross section of the through hole 22 taken along a plane parallel to the substrate 10 can have a shape of a circle, an ellipse, a polygon, or a combined shape thereof. In the example shown in the diagram, the side surface of the through hole 22 has a combined shape of a circular truncated cone and a cylinder.

If the through hole 22 has a large opening area in plan view so as to allow at least a part of the facing portion 40 to be exposed on the upper surface side of the lower electrode 20, the facing area between the lower electrode 20 and the upper electrode 30 is reduced. Accordingly, the opening area of the through hole 22 in plan view is preferably smaller. As used herein, the opening area of the through hole 22 refers to the area of the facing portion 40 or the substrate 10 seen through the through hole 22 when a single through hole 22 is viewed from above.

A plurality of through holes 22 may be formed. For example, it is possible to form a plurality of through holes 22 corresponding to the number of pairs of protruding portions 32 formed on the upper electrode 30 and facing portions 40 formed so as to correspond to the protruding portions 32. In the example shown in the diagram, in plan view, one pair of the protruding portion 32 and the facing portion 40 is formed in a substantially central portion of the upper electrode 30, but a plurality of such pairs may be formed in the periphery or end portion of the upper electrode 30, and a plurality of through holes 22 corresponding to the number of pairs are formed in positions corresponding to the positions of the pairs.

1.3. Upper Electrode

The upper electrode 30 is formed above the lower electrode 20. The upper electrode 30 and the lower electrode 20 are provided so as to be spaced apart from each other in the up down direction. The upper electrode 30 includes a protruding portion 32 that protrudes toward the through hole 22 of the lower electrode 20 (toward the substrate 10).

The upper electrode 30 may include a fixed portion 30a formed on the substrate 10, a movable portion (beam) 30b that is capable of being vibrated and is disposed so as to face the lower electrode 20, and a support portion 30c that supports the movable portion 30b by coupling the movable portion 30b to the fixed portion 30a. In this case, the protruding portion 32 is provided on the movable portion 30b. Also, the upper electrode 30 may be formed in a single-anchored beam shape (see FIG. 1), or may be formed in a double-anchored beam shape (not shown). In the case where, for example, the upper electrode 30 includes the fixed portion 30a, the support portion 30c and the movable portion 30b, the movable portion 30b is formed of a single-anchored beam or a double-anchored beam, and the support portion 30c serves as a fixed end of the beam. Also, the upper electrode 30 is formed such that at least a part thereof overlaps the lower electrode 20 in plan view. In addition, the upper electrode 30 is paired with the lower electrode 20 so as to constitute a capacitor. The upper electrode 30 can be deformed and vibrated by, for example, an electrostatic force between the upper electrode 30 and the lower electrode 20.

There is no particular limitation on the shape of the upper electrode 30, and the shape can be designed as appropriate according to the function or sensitivity required for the vibrator. In the example shown in FIG. 1, the upper electrode 30 is formed in a rectangular shape so as to overlap the lower electrode 20 in plan view, and is electrically connected to an interconnect 52.

The thickness of the upper electrode 30 can be, for example, 100 nm or more and 1 μm or less. A function of the upper electrode 30 in the vibrator 100 is to serve as an electrode that is paired with the lower electrode 20 so as to constitute a sensor unit. The upper electrode 30 is made of a conductive material, as with the lower electrode 20 described above, but the impurity concentration of the upper electrode 30 can be set independently of the impurity concentration of the facing portion 40.

The protruding portion 32 formed on the upper electrode 30 protrudes toward the substrate 10. The protruding portion 32 is provided on the lower surface side of the upper electrode 30. The protruding portion 32 is formed so as to correspond to the through hole 22 of the lower electrode 20. In other words, the protruding portion 32 protrudes toward the through hole 22 of the lower electrode 20.

The protruding portion 32 is a part of the beam of the upper electrode 30, is not in contact with the facing portion 40 in a state in which the upper electrode 30 is not displaced by vibration or the like, and is displaced together with the upper electrode 30. In the state in which the upper electrode 30 is not displaced by vibration or the like, the protruding portion 32 is located within the through hole 22 of the lower electrode 20. That is, the distance between the lower electrode 20 and the upper electrode 30 (see reference sign d2 in FIG. 3) is smaller than the height (protruding length) (see reference sign d3 in FIG. 3) of the protruding portion 32. With this configuration, the spacing distance (d2) between the lower electrode 20 and the upper electrode 30 can be reduced as compared to a configuration in which a protrusion is provided simply on the lower surface of the upper electrode 30, and it is therefore possible to increase the electrostatic capacitance of the vibrator 100, and the sensitivity as a sensor can be enhanced.

The spacing distance (d2) between the lower electrode 20 and a portion of the upper electrode 30 other than the protruding portion 32 in the state in which the upper electrode 30 is not displaced is, for example, 20 nm or more and 1 μm or less, and preferably 20 nm or more and 100 nm or less.

The protruding portion 32 may have a shape of a cylinder, a prism, a circular truncated cone, a truncated pyramid, a circular cone, a pyramid, a sphere, a spheroid of revolution, or a combined shape thereof. The shape of the protruding portion 32 may be a shape that is similar to but smaller than the outer shape of the side surface of the through hole 22. By doing so, the spacing distance between the protruding portion 32 and the lower electrode 20 within the through hole 22 can be set to a predetermined distance. The height (protruding length) (d3) of the protruding portion 32 and the thickness (height) of the facing portion 40 are set such that the distance between the facing portion 40 and the protruding portion 32 (see reference sign d1 in FIG. 3) is smaller than the distance (d2) between the lower electrode 20 and the upper electrode 30. A specific height of the protruding portion 32 is 120 nm or more and 2 μm or less. The height (protruding length) (d3) of the protruding portion 32 may be the sum of the thickness of the lower electrode 20 and the spacing distance (d2) between the lower electrode 20 and a portion of the upper electrode 30 other than the protruding portion 32.

The protruding portion 32 comes into contact with the facing portion 40 when the upper electrode 30 is displaced toward the substrate 10. In this case, the protruding portion 32 comes into contact with the facing portion 40 via the through hole 22 of the lower electrode 20. In a state in which the protruding portion 32 is in contact with the facing portion 40, the upper electrode 30 and the lower electrode 20 are spaced apart from each other unless a large external force is applied. That is, as shown in FIG. 3, the distance indicated by reference sign d1 is smaller than the distance indicated by reference sign d2, and thus in the state in which the protruding portion 32 is in contact with the facing portion 40, the upper electrode 30 and the lower electrode 20 are spaced apart from each other.

As used herein, the large external force refers to a force that is greater than a force that brings the lower electrode 20 and the upper electrode 30 closer to each other by surface tension if there is a liquid between the lower electrode 20 and the upper electrode 30, or an external force greater than an attracting force between the lower electrode 20 and the upper electrode 30 generated by a potential when the vibrator 100 is driven, such as, for example, a mechanical force or impact that brings the two electrodes into contact with each other. That is, as long as the applied force has a level amounting to the surface tension of the liquid or a level amounting to the force that drives the vibrator 100, even if the upper electrode 30 is displaced toward the substrate 10, the protruding portion 32 comes into contact with the facing portion 40 and functions as a kind of a support bar (bracing bar) (prop), as a result of which it is possible to prevent the upper electrode 30 and the lower electrode 20 from coming into contact with each other.

It is preferable that the protruding portion 32 and the facing portion 40 come into contact such that a meniscus of a liquid is not easily formed. From this point of view, qualitatively, the contact between the protruding portion 32 and the facing portion 40 is preferably so-called point contact or line contact. That is, from this point of view, the contact area when the protruding portion 32 and the facing portion 40 are in contact with each other is preferably smaller, and for example, 9 μm² (3 μm sides) or less, preferably 4 μm² (2 μm sides) or less, more preferably 1 μm² (1 μm sides) or less, and particularly preferably 0.25 μm² (0.5 μm sides) or less.

When the contact area falls in the above range, if the protruding portion 32 has a pillar shape, the mechanical strength of the protruding portion 32 may be insufficient. Accordingly, it is preferable that at least the tip portion of the protruding portion 32 has a frustum shape or a cone shape. In the example shown in the diagram, the protruding portion 32 has a circular truncated cone shape.

A plurality of protruding portions 32 may be formed. In the example shown in the diagram, one protruding portion 32 is formed in a substantially central portion of the upper electrode 30 in plan view, but the configuration is not limited thereto, and a plurality of protruding portions 32 may be formed in the periphery or end portion of the upper electrode 30.

The upper electrode 30 is formed by forming a polycrystalline silicon layer by a CVD (chemical vapor deposition) method, a sputtering method or the like, followed by patterning using a photolithography technique and an etching technique. The etching technique used at this time may be wet etching, dry etching or the like. The protruding portion 32 is made of the same material as that of the upper electrode 30, and thus a detailed description thereof is omitted here. Also, the protruding portion 32 may be formed unitarily with the upper electrode 30, or may be formed as a separate member and then bonded to the upper electrode 30.

1.4. Facing Portion

The facing portion 40 is formed on the substrate 10. The facing portion 40 faces the protruding portion 32 of the upper electrode 30. The facing portion 40 is formed within the through hole 22 of the lower electrode 20. The facing portion 40 has a function of supporting and stopping (receiving) the protruding portion 32 of the upper electrode 30 when the upper electrode 30 is displaced toward the substrate 10. As already described above, when the upper electrode 30 is displaced toward the substrate 10, the protruding portion 32 and the facing portion 40 come into contact with each other, making it difficult for the upper electrode 30 and the lower electrode 20 to come into contact with each other. Accordingly, the distance between the facing portion 40 and the protruding portion 32 (see reference sign d1 in FIG. 3) is smaller than the distance between the lower electrode 20 and the upper electrode 30 (see reference sign d2 in FIG. 3) (i.e., d1<d2). The thickness of the facing portion 40 and the height of the protruding portion 32 are selected so as to satisfy this relationship. A specific height (thickness) of the facing portion 40 can be, for example, 100 nm or more and 1 μm or less.

The facing portion 40 is electrically insulated from the lower electrode 20. That is, the facing portion 40 is spaced apart from the lower electrode 20. For this reason, even if the protruding portion 32, which is a part of the upper electrode 30, comes into contact with the facing portion 40, the insulation between the upper electrode 30 and the lower electrode 20 is maintained.

The distance (d1) between the protruding portion 32 of the upper electrode 30 and the facing portion 40 in the state in which the upper electrode 30 is not displaced is, for example, 1 nm or more and 500 nm or less, and preferably 1 nm or more and 50 nm or less.

There is no particular limitation on the shape of the facing portion 40 as long as the facing portion 40 can receive the protruding portion 32, and the shape can be, for example, a shape of a cylinder, a prism, a frustum, or the like. There is no particular limitation on the planar shape of the facing portion 40. Also, even when the facing portion 40 has a large area in plan view, as shown in the diagram, the lower electrode 20 can be disposed around the facing portion 40 so as to overlap the facing portion 40 in plan view.

A plurality of facing portions 40 corresponding to the number of protruding portions 32 are formed at positions corresponding to the positions of the protruding portions 32. In the example shown in the diagram, one facing portion 40 is formed in the through hole 22 formed at a substantially central portion of the lower electrode 20 in plan view, but the configuration is not limited thereto.

The facing portion 40 is formed by forming a polycrystalline silicon layer by, for example, a CVD (chemical vapor deposition) method, a sputtering method or the like, followed by patterning using a photolithography technique and an etching technique. The etching technique used at this time may be wet etching, dry etching or the like. In the case where both the lower electrode 20 and the facing portion 40 are made of polycrystalline silicon, the polycrystalline silicon forming the facing portion 40 has a lower impurity concentration than the impurity concentration of the polycrystalline silicon forming the lower electrode 20. The relationship of impurity concentration between the lower electrode 20 and the facing portion 40 can be achieved by using a material having a low impurity concentration when forming the facing portion 40 or by performing ion implantation on the lower electrode 20.

1.5. Advantageous Effects

The vibrator 100 of the present embodiment can have a high sensitivity when used as a sensor because the distance between the lower electrode 20 and the upper electrode 30 is smaller than the height of the protruding portion 32. Moreover, with the vibrator 100, when the lower electrode 20 and the upper electrode 30 are brought closer to each other, the protruding portion 32 and the facing portion 40 come into contact with each other before the lower electrode 20 and the upper electrode 30 come into contact with each other, and thus the spacing between the lower electrode 20 and the upper electrode 30 can be secured even if the two electrodes are brought closer to each other. Accordingly, the vibrator 100 of the present embodiment is unlikely to cause sticking when manufactured through wet etching, and thus can be manufactured in a high yield.

2. Method for Manufacturing a Vibrator

A method for manufacturing a vibrator 100 according to an embodiment of the invention includes: forming a first semiconductor layer 45 on a substrate 10; forming a facing portion 40 and a first oxide film 46 formed on a surface of the facing portion 40 by thermally oxidizing the first semiconductor layer 45; forming an opening 23 through which the first oxide film 46 is exposed by forming a second semiconductor layer 25 on the substrate 10 and the first oxide film 46 and patterning the second semiconductor layer 25; forming a lower electrode 20 and a second oxide film 26 formed on a surface of the lower electrode 20 by thermally oxidizing the second semiconductor layer 25; forming a third semiconductor layer 35 on the substrate 10, the first oxide film 46 and the second oxide film 26; forming an upper electrode 30 by patterning the third semiconductor layer 35; and etching the first oxide film 46 and the second oxide film 26.

Hereinafter, each step will be described with reference to the drawings. FIGS. 4 to 9 are diagrams illustrating a process for manufacturing a vibrator 100.

First, as shown in FIG. 4, a first underlying layer 12 and a second underlying layer 13 are formed on a support substrate 11 so as to obtain a substrate 10. The support substrate 11 is, for example, a silicon wafer. The first underlying layer 12 is formed by, for example, an STI (shallow trench isolation) method, a LOCOS method, or the like. The second underlying layer 13 is formed by, for example, a CVD (chemical vapor deposition) method, a sputtering method, or the like.

Next, as shown in FIG. 4, a first semiconductor layer 45 is formed on the substrate 10. This step can be performed by forming a semiconductor layer on the substrate 10 and patterning the semiconductor layer. The first semiconductor layer 45 is thermally oxidized so as to form a facing portion 40 and a first oxide film 46. The first semiconductor layer 45 is formed by using (for example, non-doped) polycrystalline silicon having a small impurity concentration. The first semiconductor layer 45 may contain an impurity as long as the impurity concentration can be reduced to a level lower than that of a second semiconductor layer 25, which will be described later. The first semiconductor layer 45 is formed through film-forming processing using, for example, a CVD method, a sputtering method or the like, and patterning processing using a photolithography technique and an etching technique.

Next, as shown in FIG. 5, the first semiconductor layer 45 is thermally oxidized so as to form a facing portion 40 and a first oxide film 46 formed on a surface of the facing portion 40. There is no particular limitation on the conditions for thermal oxidation, and conditions are selected such that the first oxide film 46 has a smaller thickness than that of a second oxide film 26, which will be described later. Because the impurity concentration of the first semiconductor layer 45 is smaller than that of the second semiconductor layer 25, even if the conditions for thermal oxidation for forming the first oxide film 46 and the conditions for thermal oxidation for forming the second oxide film 26 are the same, the growth rate (oxidation rate) of the first oxide film 46 is lower, and thus the first oxide film 46 has a smaller thickness than that of the second oxide film 26. The thickness of the first oxide film 46 formed in this step defines the distance between the protruding portion 32 and the facing portion 40 (see reference sign d1 in FIG. 3).

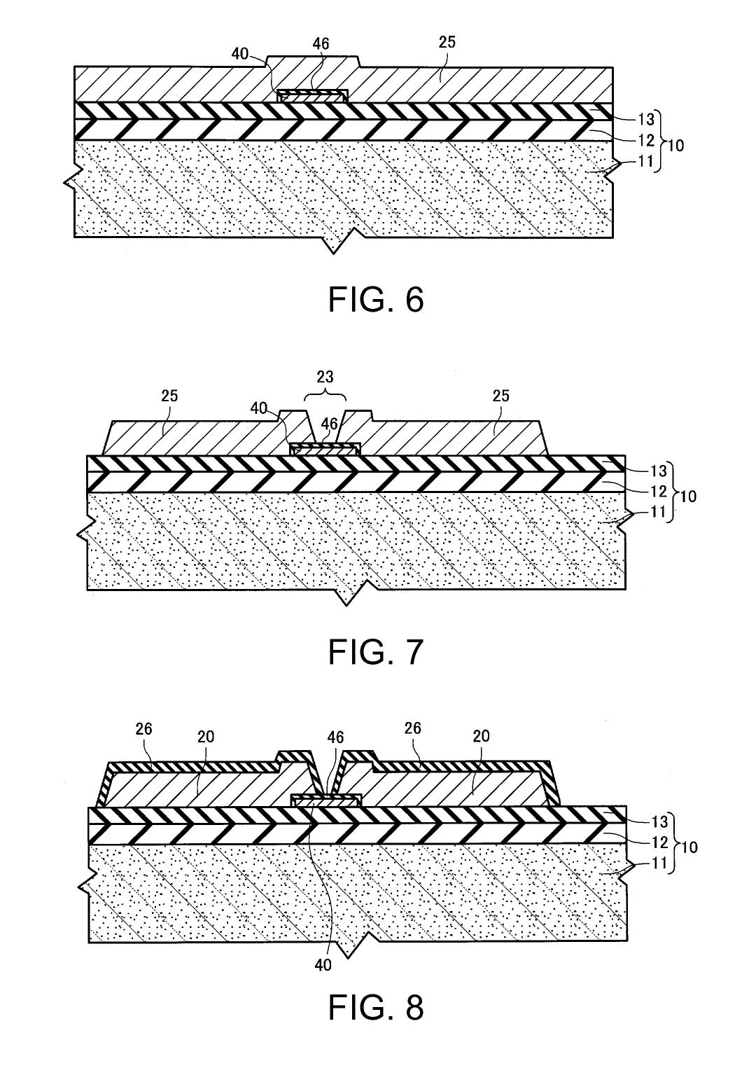

Next, as shown in FIG. 6, a second semiconductor layer 25 is formed on the substrate 10 and the first oxide film 46, and then as shown in FIG. 7, the second semiconductor layer 25 is patterned so as to form an opening 23 through which the first oxide film 46 is exposed. Through the patterning performed in this step, the outer shape of the second semiconductor layer 25, which will become a lower electrode 20, is formed.

The second semiconductor layer 25 is formed by using polycrystalline silicon. The second semiconductor layer 25 is formed so as to have a higher impurity concentration than that of the first semiconductor layer 45. The second semiconductor layer 25 is formed by, for example, forming a film by a CVD method or a sputtering method by using impurity-containing (doped) polycrystalline silicon. The conductivity of the second semiconductor layer 25 is thereby secured. Also, in the case where the second semiconductor layer 25 is formed by using non-doped polycrystalline silicon or polycrystalline silicon having a low impurity concentration, by performing appropriate ion implantation, the second semiconductor layer 25 having an increased conductivity and a higher impurity concentration than the impurity concentration of the first semiconductor layer 45 can be formed. Also, even in the case where the same material is selected to form the first semiconductor layer 45 and the second semiconductor layer 25, the impurity concentration of the second semiconductor layer 25 can be increased as compared to the impurity concentration of the first semiconductor layer 45.

The area of the first oxide film 46 that is exposed on the upper surface side in this step is related to the shape of the tip of the protruding portion 32, and thus is set in consideration of the thickness of the second oxide film 26. If the exposed area of the first oxide film 46 is too small, the first oxide film 46 may be covered by the second oxide film 26, as a result of which the distance (d1) between the protruding portion 32 and the facing portion 40 may not be defined by the first oxide film 46.

In the patterning performed in this step, by etching the end portions of the second semiconductor layer 25 (the end portion of the pattern) at an angle (into a tapered shape) as shown in the diagram, an opening 23, which will be a part of the through hole 22, can be formed so as to have a tapered shape, and the protruding portion 32 of the upper electrode 30 can be formed in a tapered shape similar to the shape of the side surface of the through hole 22.

Then, as shown in FIG. 8, the second semiconductor layer 25 is thermally oxidized so as to form a lower electrode 20 and a second oxide film 26 formed on a surface of the lower electrode 20. There is no particular limitation on the conditions for thermal oxidation, and conditions are selected such that the second oxide film 26 has a thickness larger than that of the first oxide film 46. The thickness of the second oxide film 26 formed in this step defines the distance between the lower electrode 20 and the upper electrode 30 (see reference sign d2 in FIG. 3). In this step, the first oxide film 46 formed on the surface of the facing portion 40 may grow to have a large thickness, but as described above, the film-forming speed (oxidation rate) of the second oxide film 26 is higher, and thus in the end, the first oxide film 46 is formed so as to have a smaller thickness than that of the second oxide film 26.

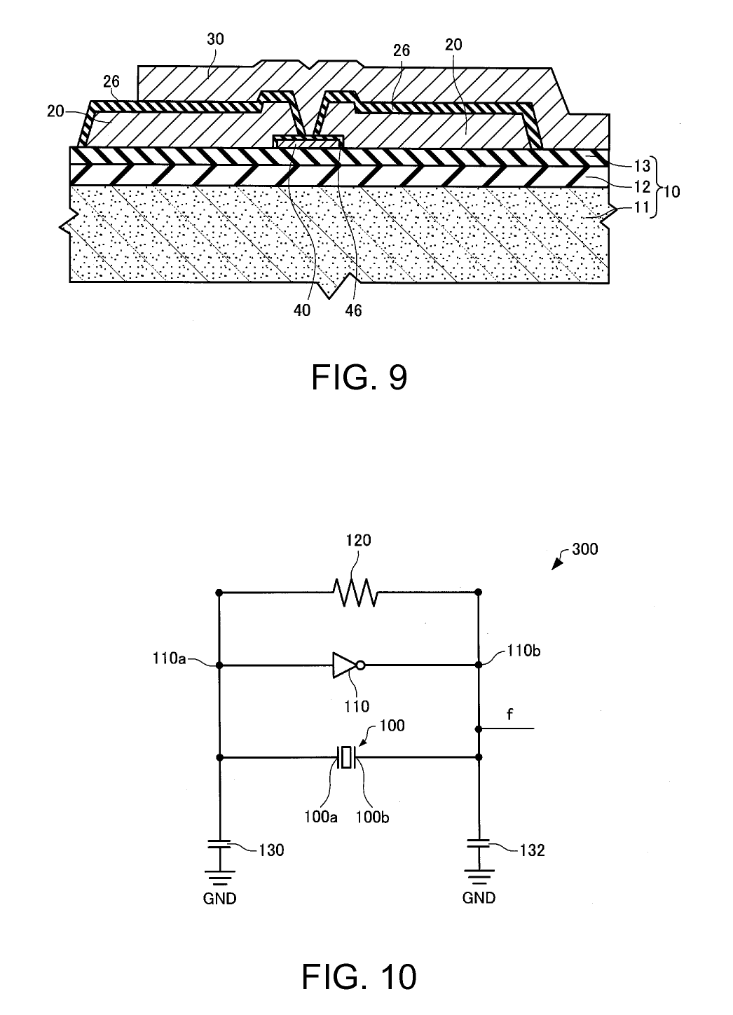

Next, a third semiconductor layer 35 is formed on the substrate 10, the first oxide film 46 and the second oxide film 26. As shown in FIG. 9, the third semiconductor layer 35 is then patterned so as to form an upper electrode 30. The third semiconductor layer 35 is formed by using polycrystalline silicon. In order to increase conductivity, ion implantation may be performed on the third semiconductor layer 35. The impurity concentration of the third semiconductor layer 35 can be arbitrarily set as long as the conductivity of the upper electrode 30 can be secured. The third semiconductor layer 35 is formed through film-forming processing using, for example, a CVD method, a sputtering method or the like, and patterning processing using a photolithography technique and an etching technique. Through this, an upper electrode 30 is formed.

Then, by etching the first oxide film 46 and the second oxide film 26, a vibrator 100 as shown in FIG. 1 can be manufactured. The etching in this step is performed by wet etching using hydrofluoric acid, buffered hydrogen fluoride (a mixed solution of hydrofluoric acid and ammonium fluoride), and the like. This step may further include a cleaning step performed after the etching step.

According to the method for manufacturing a vibrator of the present embodiment, the thickness of the first oxide film 46 can be reduced as compared to the thickness of the second oxide film 26. It is therefore possible to easily manufacture a vibrator 100 in which the distance between the facing portion 40 and the protruding portion 32 is smaller than the distance between the lower electrode 20 and the upper electrode 30. Furthermore, in the step of wet-etching the first oxide film 46 and the second oxide film 26, sticking is unlikely to occur, and thus the vibrator 100 can be manufactured with good productivity (yield and the like).

3. Electronic Appliance

An electronic appliance according to an embodiment of the invention includes a vibrator described above, and a circuit unit that drives the vibrator. Although not shown, the electronic appliance can be, for example, an apparatus having a configuration in which a cavity is formed on the substrate 10 of the vibrator 100 described above, the lower electrode 20, the upper electrode 30 and the facing portion 40 are housed in the cavity, and a capacitance element (capacitor), a transistor and the like are provided on the same substrate 10.

A case will be described in which the electronic appliance of the present embodiment is an oscillator, with reference to the drawings. FIG. 10 is a circuit diagram showing an oscillator 300 according to the present embodiment. As shown in FIG. 10, the oscillator 300 includes a vibrator 100 described above, and an inverting amplifier circuit 110. The vibrator 100 includes a first terminal 100a electrically connected to the interconnect 51 connected to the lower electrode 20, and a second terminal 100b electrically connected to the interconnect 52 connected to the upper electrode 30. The first terminal 100a of the vibrator 100 is at least AC connected to an input terminal 110a of the inverting amplifier circuit 110. The second terminal 100b of the vibrator 100 is at least AC connected to an output terminal 110b of the inverting amplifier circuit 110.

In the example shown in the diagram, the inverting amplifier circuit 110 is constituted by a single inverter, but may be constituted by combining a plurality of inverters (inverting circuits) and amplifier circuits so that desired oscillation conditions are satisfied.

The oscillator 300 may include a feedback resistor for the inverting amplifier circuit 110. In the example shown in FIG. 10, the input terminal and the output terminal of the inverting amplifier circuit 110 are connected via a resistor 120.

The oscillator 300 includes a first capacitor 130 (which may be, for example, a capacitor formed on the substrate 10 of the vibrator 100) connected between the input terminal 110a of the inverting amplifier circuit 110 and a reference potential (ground potential), and a second capacitor 132 (which may be, for example, another capacitor formed on the same substrate) connected between the output terminal 110b of the inverting amplifier circuit 110 and a reference potential (ground potential). With this configuration, the vibrator 100 and the capacitors 130 and 132 can form an oscillator circuit constituting a resonance circuit. The oscillator 300 outputs an oscillator signal f obtained with this oscillator circuit.

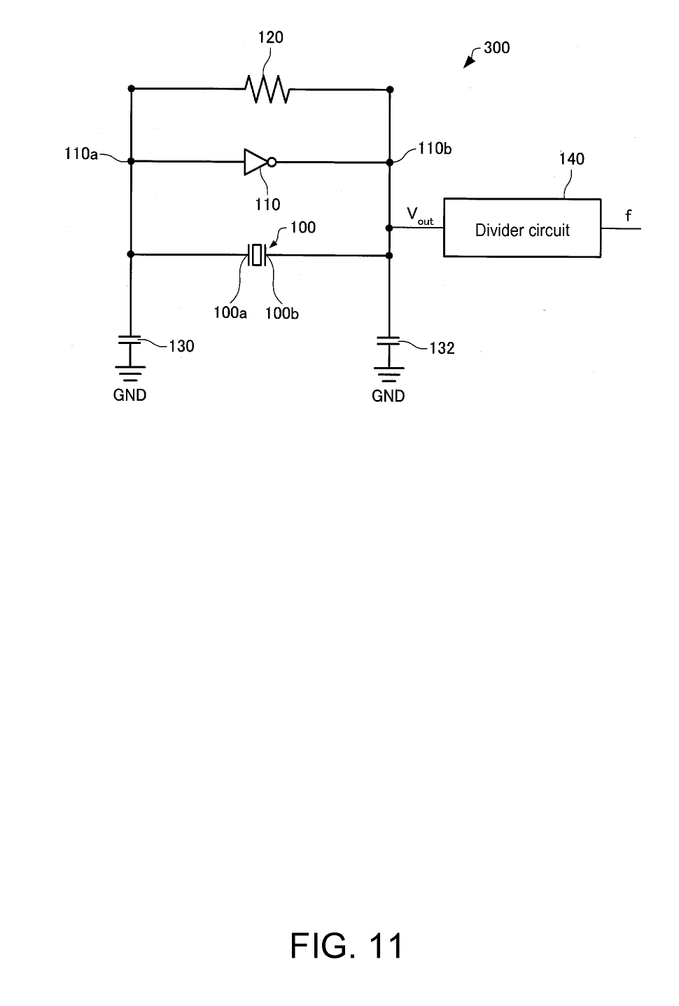

As shown in FIG. 11, the oscillator 300 may further include a divider circuit 140. The divider circuit 140 divides an output signal Vₒᵤₜ from the oscillator circuit, and outputs an oscillator signal f. The oscillator 300 can thereby provide, for example, an output signal having a frequency lower than the frequency of the output signal Vₒᵤₜ. The inverting amplifier circuit 110, the resistor 120, the capacitors 130 and 132, and the divider circuit 140 may together constitute a circuit unit formed on the substrate 10.

The embodiments and the variation described above are merely examples, and thus the invention is not limited thereto. It is possible to, for example, combine the embodiments and the variation as appropriate.

The invention is not limited to the embodiments given above, and various modifications are possible. For example, the invention encompasses configurations that are substantially the same as those described in the embodiments given above (for example, configurations having the same functions, methods and results, or configurations having the same objects and advantageous effects). The invention also encompasses configurations obtained by replacing a part that is not essential to the configurations described in the embodiments given above by another part. The invention also encompasses configurations that can achieve the same advantageous effects or the same objects as those described in the embodiments given above. The invention also encompasses configurations obtained by adding a known technique to the configurations described in the embodiments given above.

The entire disclosure of Japanese Patent Application No. 2014-031621, filed Feb. 21, 2014 is expressly incorporated by reference herein.

What is claimed is:

1. A vibrator comprising:
a substrate;
a lower electrode that is formed on the substrate and has a through hole formed therein;
an upper electrode that is disposed above the lower electrode so as to be spaced apart from the lower electrode, and includes a protruding portion that protrudes toward the through hole; and
a facing portion that is formed on the substrate, and faces the protruding portion,
wherein a distance between the facing portion and the protruding portion is smaller than a distance between the lower electrode and the upper electrode.

2. The vibrator according to claim 1,
wherein the protruding portion comes into contact with the facing portion when the upper electrode is displaced toward the substrate, and
a contact area when the protruding portion and the facing portion are in contact with each other is 1 μm² or less.

3. The vibrator according to claim 1,
wherein the upper electrode includes a fixed portion disposed on the substrate, a movable portion disposed so as to face the lower electrode, and a support portion that supports the movable portion by coupling the movable portion to the fixed portion, and
the protruding portion is disposed on the movable portion.

4. A method for manufacturing a vibrator, the method comprising:
forming a first semiconductor layer on a substrate;
forming a facing portion and a first oxide film formed on a surface of the facing portion by thermally oxidizing the first semiconductor layer;
forming an opening through which the first oxide film is exposed by forming a second semiconductor layer on the substrate and the first oxide film, and patterning the second semiconductor layer;
forming a lower electrode and a second oxide film formed on a surface of the lower electrode by thermally oxidizing the second semiconductor layer;
forming a third semiconductor layer on the substrate, the first oxide film and the second oxide film;
forming an upper electrode by patterning the third semiconductor layer; and
etching the first oxide film and the second oxide film,
wherein the second semiconductor layer has a higher impurity concentration than the first semiconductor layer.

5. The method for manufacturing a vibrator according to claim 4, comprising implanting an impurity into the second semiconductor layer, which is performed between the step of forming the second semiconductor layer and the step of forming the upper electrode.

6. An electronic appliance comprising the vibrator according to claim 1, and a circuit unit that drives the vibrator.

7. An electronic appliance comprising the vibrator according to claim 2, and a circuit unit that drives the vibrator.

8. An electronic appliance comprising the vibrator according to claim 3, and a circuit unit that drives the vibrator.
